(19) United States
(12) Patent Application Publication
(10) Pub. No.: US 2015/0001512 A1
(43) Pub. Date: Jan. 1, 2015

(54) PIXEL STRUCTURE AND MASK FOR MANUFACTURING THE SAME

(71) Applicant: Ye Xin Technology Consulting Co., Ltd., Hsinchu (TW)

(72) Inventors: CHUN-CHIEH HUANG, Hsinchu (TW); WEI-LI WANG, Hsinchu (TW)

(21) Appl. No.: 14/320,756

(22) Filed: Jul. 1, 2014

(30) Foreign Application Priority Data
Jul. 1, 2013 (TW) 102123544

(51) Int. Cl. H01L 27/32; B05C 21/00

(52) U.S. Cl. CPC H01L 27/3218; B05C 21/005
USPC 257/40; 118/504

(57) ABSTRACT

A pixel structure of an organic light emitting diode display includes a number of pixels arranged as a matrix and formed on a substrate. Each of the pixels includes a first sub-pixel of one color, and second and third sub-pixels each of different colors. The pixel structure at least includes a first sub-pixel column pair having two adjacent first sub-pixel columns with a first interval defined therebetween, a third sub-pixel column pair having two adjacent second sub-pixel columns with the first interval defined therebetween, and a second sub-pixel column between the first sub-pixel column pair and the third sub-pixel column pair. The pixel structure defines a second interval between the first sub-pixel column pair and the second sub-pixel column, and between the third sub-pixel column pair and the second sub-pixel column.

### FIELD

The disclosure generally relates to organic light emitting diode (OLED) display manufacturing technologies.

### BACKGROUND

An OLED display panel includes a number of pixels formed on a substrate. Each of the pixels includes at least one red sub-pixel, one green sub-pixel, and one blue sub-pixel. The sub-pixels with different colors are made of different OLED material. In order to achive a high pixel density, an interval between two adjacent sub-pixels of different colors needs to be smaller. OLED materials of different colors mix and lose identity in two adjacent sub-pixels which are very close together.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the views.

FIG. 1 is a diagrammatic view of a pixel structure of a first embodiment.

FIG. 2 is a diagrammatic view of a pixel structure of a second embodiment.

FIG. 3 is a diagrammatic view of a pixel structure of a third embodiment.

FIG. 4 is a diagrammatic view of a mask for manufacturing a first sub-pixel of the pixel structure of FIG. 1.

FIG. 5 is a diagrammatic view of a mask for manufacturing a third sub-pixel of the pixel structure of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one.”

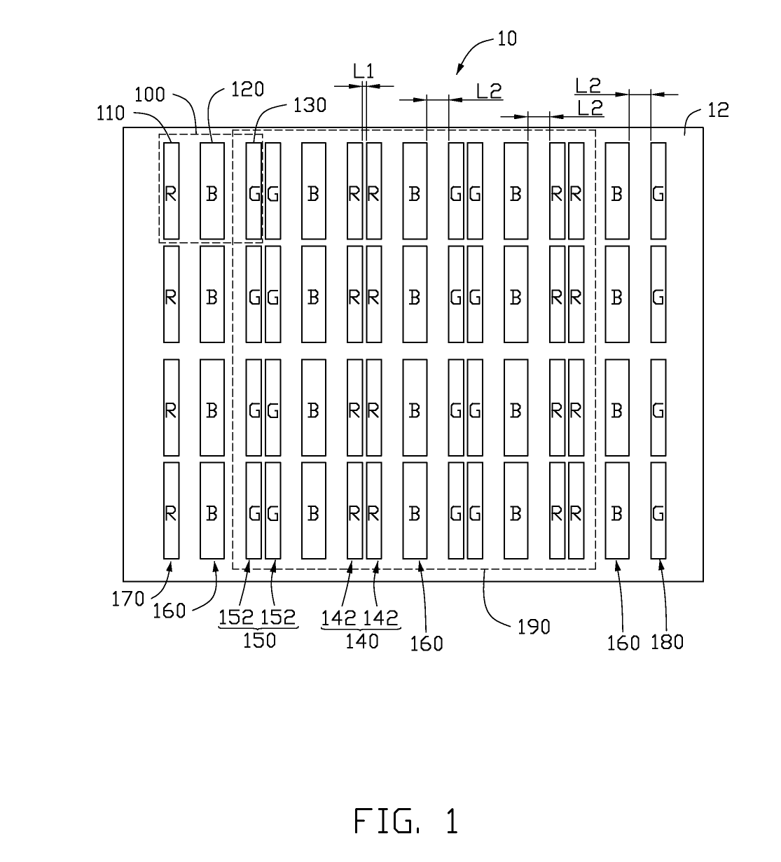

FIG. 1 illustrates a pixel structure 10 of an OLED display panel of a first embodiment. The pixel structure 10 of the first embodiment includes a number of pixels 100 arranged as a matrix and formed on a substrate 12. Each of the pixels 100 includes a first sub-pixel 110, a second sub-pixel 120, and a third sub-pixel 130. Colors of the first sub-pixel 110, the second sub-pixel 120, and the third sub-pixel 130 are different from each other. In this embodiment, the first sub-pixel 110 is a red sub-pixel, the second sub-pixel 120 is a blue sub-pixel, and the third sub-pixel 130 is a green sub-pixel.

The pixel structure 10 can include a first sub-pixel column pair 140, a third sub-pixel column pair 150, and a second sub-pixel column 160 which is between the first sub-pixel column pair 140 and the third sub-pixel column pair 150. The first sub-pixel column pair 140 includes two adjacent first sub-pixel columns 142 and defines a first interval L1 between these two adjacent first sub-pixel columns 142. The third sub-pixel column pair 150 includes two adjacent third sub-pixel columns 152 and the first interval L1 is also defined between these two adjacent third sub-pixel columns 152. The pixel structure 10 defines a second interval L2 between the first sub-pixel column pair 140 and the second sub-pixel column 160, and between the third sub-pixel column pair 150 and the second sub-pixel column 160.

In detail, the sub-pixels 110, 120, and 130 are divided into a first column of sub-pixels 170, a final column of sub-pixels 180, and a middle sub-pixel area 190 located between the first column of sub-pixels 170 and the final column of sub-pixels 180. One second sub-pixel column 160 is located between the first column of sub-pixels 170 and the middle sub-pixel area 190 and the other second sub-pixel column 160 is located between the middle sub-pixel area 190 and the final column of sub-pixels 180. The second interval L2 is also defined between the second sub-pixel column 160 and the first column of sub-pixels 170, and between the second sub-pixel column and the final column of sub-pixels 180. The middle sub-pixel area 190 includes a number of first sub-pixel column pairs 140, a number of third sub-pixel column pairs 150, and a number of second sub-pixel columns 160. The first sub-pixel column pairs 140 and the third sub-pixel column pairs 150 are alternately arranged. The second sub-pixel column 160 is located between the first sub-pixel column pair 140 and the third sub-pixel column pair 150. In this embodiment, the first column of sub-pixels 170 contains the first sub-pixels 110 and the final column of sub-pixels 180 contains the third sub-pixels 130. An outermost sub-pixel column pair in the middle sub-pixel area 190 which corresponding to the first column of sub-pixels 170 is the third sub-pixel column pair 150. An outermost sub-pixel column pair of the sub-pixels in the middle sub-pixel area 190 which corresponds to the final column of the sub-pixels is the first sub-pixel column pair 140.

In the pixel structure 10, the first interval L1 is greater than the second interval L2. For example, when a pixel density of the OLED display panel is 300 pixels per inch (PPI), a width of the first sub-pixel 110 is 6 micrometers, the first interval L1 is 3 micrometer and the second interval L2 is 26 micrometers. Because the pixel structure 10 has a number of the greater second interval L2 between the adjacent sub-pixels 110, 120, and 130 of different colors, OLED materials of different colors are not mixed up. The pixel structure 10 has a number of the lesser first interval L1 between the adjacent sub-pixels 110, 120, and 130, which are all of same color, thus the pixel density of the OLED display panel can be increased.

The sub-pixels 110, 120, and 130 can be, but are not limited to being, in a rectangular configuration. An area of the red sub-pixel 110 is the same as an area of the green sub-pixel 120. An area of the blue sub-pixel 130 is greater than the individual areas of each of the red and green sub-pixels, 110 and 120.

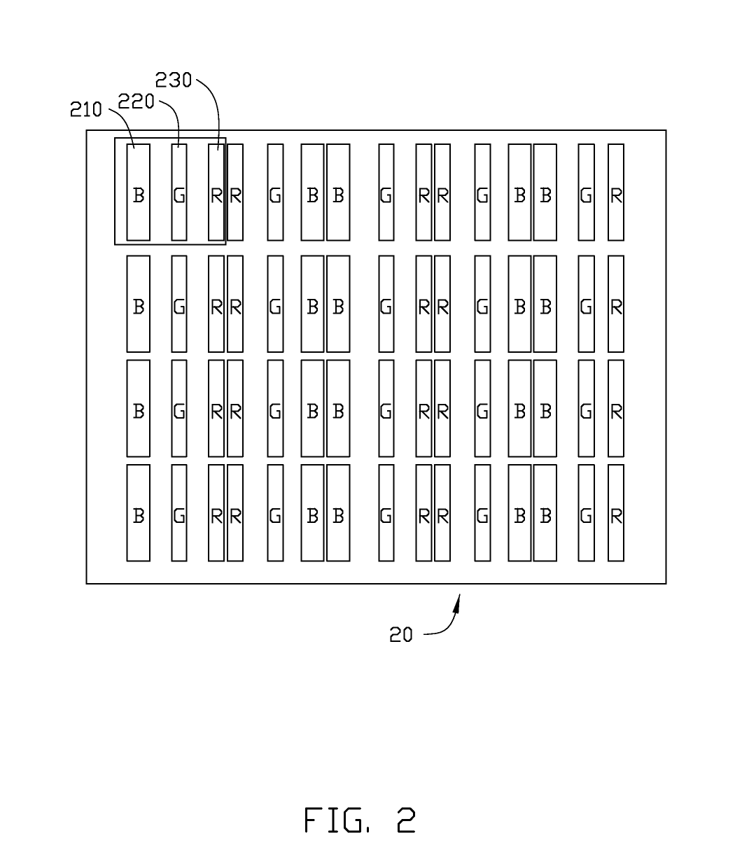

FIG. 2 illustrates a pixel structure 20 of an OLED display panel of a second embodiment. The pixel structure 20 of the second embodiment is similar to the pixel structure 10 of the first embodiment except that the first sub-pixel 210 is a blue sub-pixel, the second sub-pixel 220 is a green sub-pixel, and the third sub-pixel 230 is a red sub-pixel.

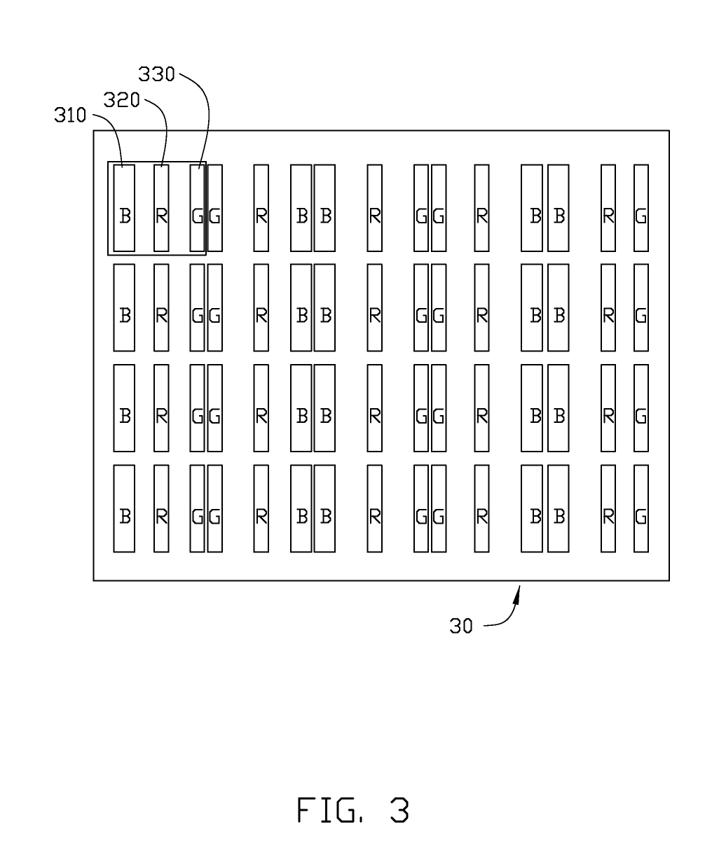

FIG. 3 illustrates a pixel structure 30 of an OLED display panel of a third embodiment. The pixel structure 30 of the third embodiment is similar to the pixel structure 10 of the first embodiment except that the first sub-pixel 310 is a blue sub-pixel, the second sub-pixel 320 is a red sub-pixel, and the third sub-pixel 330 is a green sub-pixel.

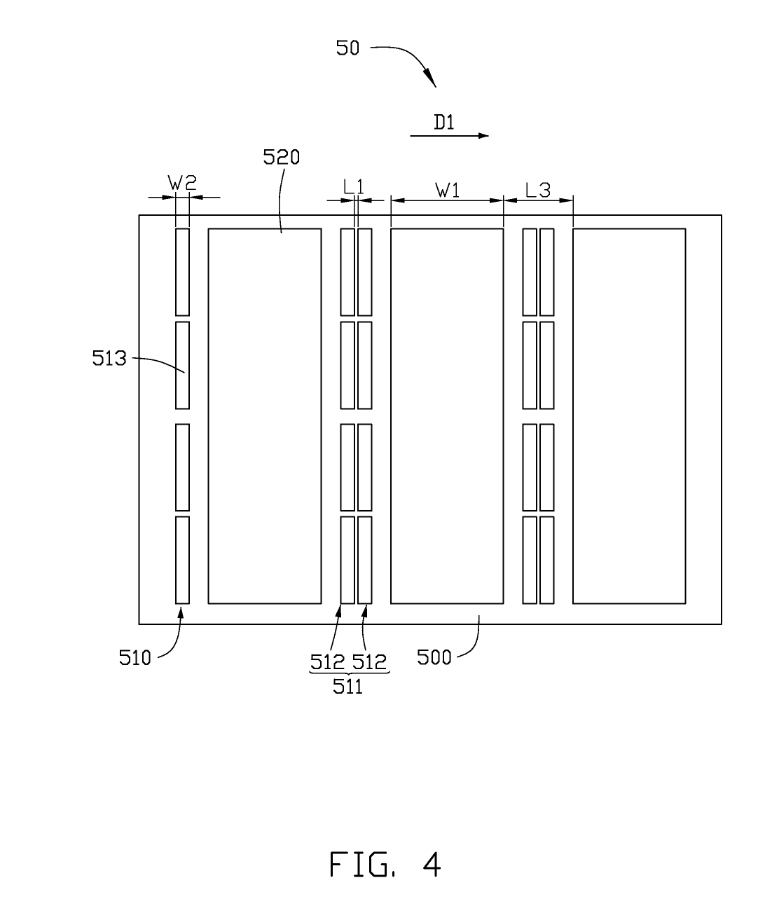

FIG. 4 illustrates a mask 50 for manufacturing the first sub-pixels 110 of the OLED display panel. The mask 50 can include a base board 500 and defines a stacked column of openings 510 near one of two opposite peripheries of the base board 500 arranged along a horizontal direction D1 of the base board 500, a number of openings column pairs 511 parallel to the column of openings 510 and a shielding part 520 located after the column of openings 510 and then between every two adjacent column pair openings 511. The column of openings 510, the opening column pairs 511 and the shielding part 520 are orderly aligned with each other along and across the horizontal direction D1 of the base board 500. Each of the opening column pair 511 includes two closely adjacent columns of openings 512 and the first interval L1 is defined between each two closely adjacent columns of openings 512. A number of openings 513 of the mask 50 restricts OLED material of the first sub-pixels 110 from being deposited on certain predetermined positions on the substrate 12, to form a pattern of the first sub-pixel 110. In this embodiment, the column of openings 510 is defined near a left periphery of the base board 500

A size and configuration of each opening 513 corresponds to the size and configuration of the first sub-pixel 110. To form the OLED display panel of 300 PPI, a width W2 of each opening 513 is 6 micrometers, the first interval L1 of the opening column pair 511 is 3 micrometers, a width W1 of the shielding part 520 is 93 micrometers and a third interval L3 between two adjacent shielding parts is 43 micrometers.

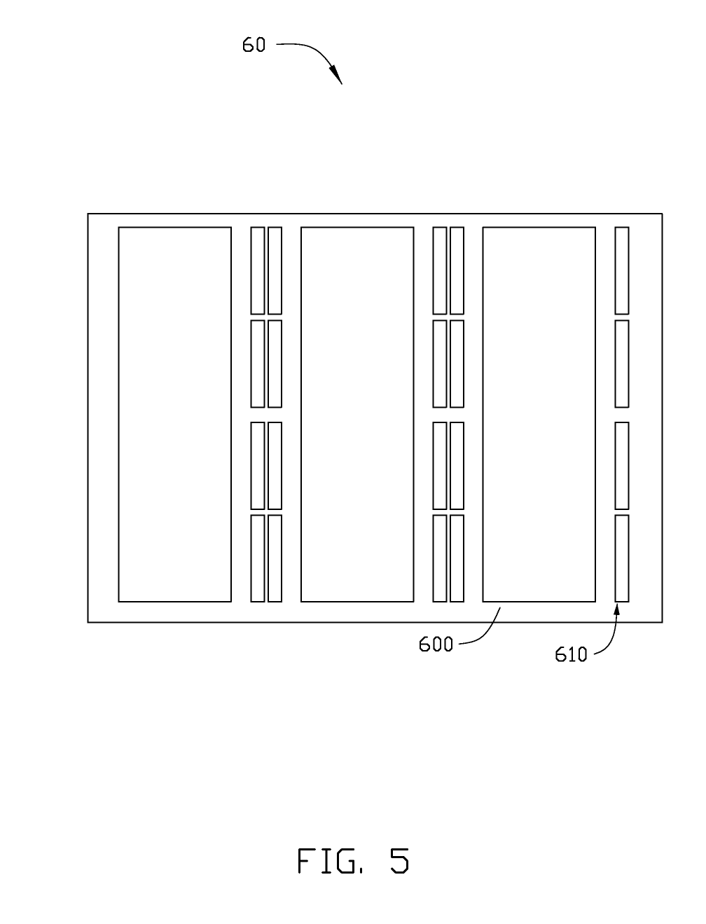

FIG. 5 illustrates a mask 60 for manufacturing the third sub-pixels 130 of the OLED display panel. The structure of the mask 60 is similar to the structure of the mask 50 for manufacturing the first sub-pixels 110 of the OLED display panel except that the column of openings 610 is defined near a right periphery of the base board 600.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments.

What is claimed is:

1. A pixel structure of an organic light emitting diode display comprising:
a plurality of pixels arranged as a matrix and formed on a substrate, each of the pixels comprising a first sub-pixel, a second sub-pixel and a third sub-pixel;
the first sub-pixel having a first color;
the second sub-pixel having a second color;
the third sub-pixel having a third color, wherein the first color, the second color and the third color are different from one another;
a first sub-pixel column pair comprising two adjacent first sub-pixel columns with a first interval defined therebetween;
a second sub-pixel column pair; and
a third sub-pixel column pair comprising two adjacent third sub-pixel columns with a first interval defined therebetween, wherein the second sub-pixel column pair is located between the first sub-pixel column pair and the third sub-pixel column pair;
wherein a second interval is defined between the first sub-pixel column pair and the second sub-pixel column and between the third sub-pixel column pair and the second sub-pixel column.

2. The pixel structure of claim 1, wherein the pixel structure comprises a first column of sub-pixels, a final column of sub-pixels, a middle sub-pixels area located between the first column of sub-pixels and the final column of sub-pixels, one second sub-pixel column located between the first column of sub-pixels and the middle sub-pixel area and the other one second sub-pixel column located between the middle sub-pixel area and the final column of sub-pixels.

3. The pixel structure of claim 2, wherein the middle sub-pixel area comprises a plurality of first sub-pixel column pairs, a plurality of third sub-pixel column pairs and a plurality of second sub-pixel columns, the first sub-pixel column pairs and the third sub-pixel column pairs are alternately arranged, and the second sub-pixel columns are correspondingly located between the first sub-pixel column pair and the third sub-pixel column pair.

4. The pixel structure of claim 3, wherein the first column of sub-pixels are the first sub-pixels, the final column of sub-pixels are the third sub-pixels, an outermost sub-pixel column pair in the middle sub-pixel area corresponding to the first column of sub-pixels is the third sub-pixel column pair, and an outermost sub-pixel column pair in the middle sub-pixel area corresponding to the final column of the sub-pixels is the first sub-pixel column pair.

5. The pixel structure of claim 2, wherein the second interval is also correspondingly defined between the second sub-pixel column and the first column of sub-pixels and between the secong sub-pixel column and the final column of sub-pixels.

6. The pixel structure of claim 5, wherein the first interval is greater than the second interval.

7. The pixel structure of claim 1, wherein the first sub-pixel is a red sub-pixel, the second sub-pixel is a blue sub-pixel, and the third sub-pixel is a green sub-pixel.

8. The pixel structure of claim 1, wherein the first sub-pixel is a blue sub-pixel, the second sub-pixel is a green sub-pixel, and the third sub-pixel is a red sub-pixel.

9. The pixel structure of claim 1, wherein the first sub-pixel is a red sub-pixel, the second sub-pixel is a blue sub-pixel and the third sub-pixel is a green sub-pixel.

10. A mask for manufacturing sub-pixels of an organic light emitting diode display panel comprising:
a base board;
a column of openings defined near one of two opposite peripheries of the base board along a horizontal direction of the base board;
a plurality of opening column pairs defined in the base board; and
a shielding part located after the column of openings and then between every two adjacent opening column pairs;
wherein the column of openings, the opening column pairs and the shielding part are aligned with each other along and across the horizontal direction of the base board, and each of the opening column pair comprises two closely adjacent columns of openings and a first interval is defined between each two closely adjacent columns of openings.

11. The mask of claim 10, wherein the column of opening is defined near a right periphery of the base board.

12. The mask of claim 10, wherein the column of opening is defined near a left periphery of the base board.
